(19) United States
(12) Patent Application Publication
(10) Pub. No.: US 2016/0086903 A1
(43) Pub. Date: Mar. 24, 2016

(54) SEMICONDUCTOR STRUCTURE AND METHOD OF FABRICATING THE SAME

(71) Applicant: Siliconware Precision Industries Co., Ltd., Taichung (TW)

(72) Inventors: Ching-Wen Chiang, Taichung (TW); Kuang-Hsin Chen, Taichung (TW); Hsien-Wen Chen, Taichung (TW)

(21) Appl. No.: 14/672,268

(22) Filed: Mar. 30, 2015

(30) Foreign Application Priority Data
Sep. 19, 2014 (TW) 103132405

(51) Int. Cl. H01L 23/00; H01L 21/56; H01L 23/31

(52) U.S. Cl. CPC H01L 24/14; H01L 24/17; H01L 23/3157; H01L 24/83; H01L 21/563; H01L 24/11; H01L 2924/01029; H01L 2924/01022

(57) ABSTRACT

The present invention provides a semiconductor structure and a method of fabricating the same. The semiconductor structure includes a carrier, a semiconductor chip and an encapsulant. The semiconductor chip is disposed on the carrier, and has opposing non-active and active surfaces. The non-active surface is coupled to the carrier, and the active surface has a plurality of metallic pillars formed thereon. A under bump metallogy layer is formed between the metallic pillars and the active surface and on side surfaces of the metal pillars. The surface of the encapsulant is flush with end surfaces of the metallic pillars. Therefore, the product yield is increased significantly.

### BACKGROUND OF THE INVENTION

1. Field of the Invention

The present invention relates to semiconductor structures and methods of fabricating the same, and, more particularly, to a semiconductor structure including a semiconductor chip having metallic pillars formed thereon, and a method of fabricating the semiconductor structure.

2. Description of Related Art

With the rapid growth in electronic industry, there is an increasing need in developing electronic products with multi-functionality and high performance and miniaturization, thereby facilitating the development of several different types of packaging technologies.

FIGS. 1A-1G are cross-sectional views illustrating a method of fabricating a conventional package structure.

As shown in FIG. 1A, a semiconductor chip 10 is provided. The semiconductor chip 10 has opposing active and non-active surfaces 10a and 10b. A plurality of electrode pads 101 are formed on the active surface 10a. A passivation layer 11 having a plurality of passivation layer holes 110 is formed on the active surface 10a and the electrode pads 101, with the electrode pads 101 exposed from the corresponding passivation layer holes 110. A titanium layer 121 and a copper layer 122 of the under bump metallogy layer (UBM) 12 are sequentially formed on the passivation layer 11 and the electrode pads 101. A resist layer 13 having a plurality of resist layer holes 130 is formed on the copper layer 122, with the resist layer holes 130 corresponding in position to the passivation layer holes 110 and the periphery thereof.

As shown in FIG. 1B, copper bumps 14 are formed in the resist layer holes 130 by an electroplating method.

As shown in FIG. 1C, the resist layer 13 and the titanium layer 121 and the copper layer 122 covered by the resist layer 13 are removed.

As shown in FIG. 1D, through an adhesive layer 15, the non-active surface 10b of the semiconductor chip 10 is mounted to a bottom surface of a groove 160 of the carrier 16.

As shown in FIG. 1E, an encapsulant 17 is formed on the carrier 16 and encapsulates the semiconductor chip 10 and the copper bumps 14.

As shown in FIG. 1F, a plurality of encapsulant holes 170 are formed, with the copper bumps 14 exposed from the corresponding encapsulant holes 170.

As shown in FIG. 1G, conductive vias 18 are formed on the copper bumps 14 in the encapsulant holes 170. A redistribution layer (not shown) is formed on the encapsulant 17 and the conductive vias 18 and electrically connected with the semiconductor chip 10.

However, the copper bumps, since formed in the resist layer holes 130 by an electroplating process, are not at the same level, and the copper bumps formed in the resist layer holes subsequently suffer from poor contact problem. Besides, an alignment problem occurs when the encapsulant holes that correspond to the copper bumps are formed. As a result, the copper bumps have poor electrical connection quality, and the product yield is thus reduced.

Accordingly, there is an urgent need to solve the above-mentioned problems of the prior art.

### SUMMARY OF THE INVENTION

In view of the foregoing objectives, the present invention provides a semiconductor package, comprising: a semiconductor chip having a non-active surface and an active surface opposing the non-active surface; a plurality of metallic pillars formed on the active surface; and an under bump metallogy layer formed between the metallic pillars and the active surface and on side surfaces of the metallic pillars.

The present invention further provides a method of fabricating a semiconductor structure, comprising: disposing on a carrier a semiconductor chip having opposing active and non-active surfaces, with the non-active surface being coupled to the carrier, wherein a plurality of metallic pillars are formed on the active surface, and an under bump metallogy layer is formed between the metallic pillars and the active surface and on side surfaces of the metallic pillars; and forming on the carrier an encapsulant that encapsulates the semiconductor chip and has a surface flush with end surfaces of the metallic pillars.

The present invention further provides a method of fabricating a semiconductor structure, comprising: forming a dielectric layer having a plurality of holes on an active surface of a semiconductor chip, with a portion of the active surface exposed from the holes; forming an under bump metallogy layer on the dielectric layer, the walls of the holes, and the portion of the active surface exposed from the holes; forming a metal layer on the under bump metallogy layer; and removing a portion of the metal layer and the under bump metallogy layer that is higher than the dielectric layer, and forming a plurality of metallic pillars on the portion of the active surface exposed from the holes.

In summary, the present invention is characterized by forming a dielectric layer exposing the electrode pads, followed by forming an under bump metallogy layer and a metal layer, and then removing parts of the thickness of the under bump metallogy layer and metal layer, so as to solve the unevenness of conventional metallic pillars; Moreover, an encapsulant is formed to encapsulate the semiconductor chip and the metallic pillars after the semiconductor chip is coupled to the carrier, of which the encapsulant and metallic pillars are subsequently grinded to expose the metallic pillars. As a result, the conventional method of forming encapsulant holes is not required to expose the metallic pillars, thereby solving the conventional problems in the prior art such as alignment deviation, and uneven thickness of the semiconductor chip and the adhesive layer.

### BRIEF DESCRIPTION OF THE DRAWINGS

FIGS. 1A-1G are cross-sectional views illustrating a method of fabricating a conventional package structure;

FIGS. 2A-2I are cross-sectional views illustrating a method of fabricating a semiconductor structure of a first embodiment according to the present invention; and

FIGS. 3A-3D are cross-sectional views illustrating a method of fabricating a semiconductor structure of a second embodiment according to the present invention.

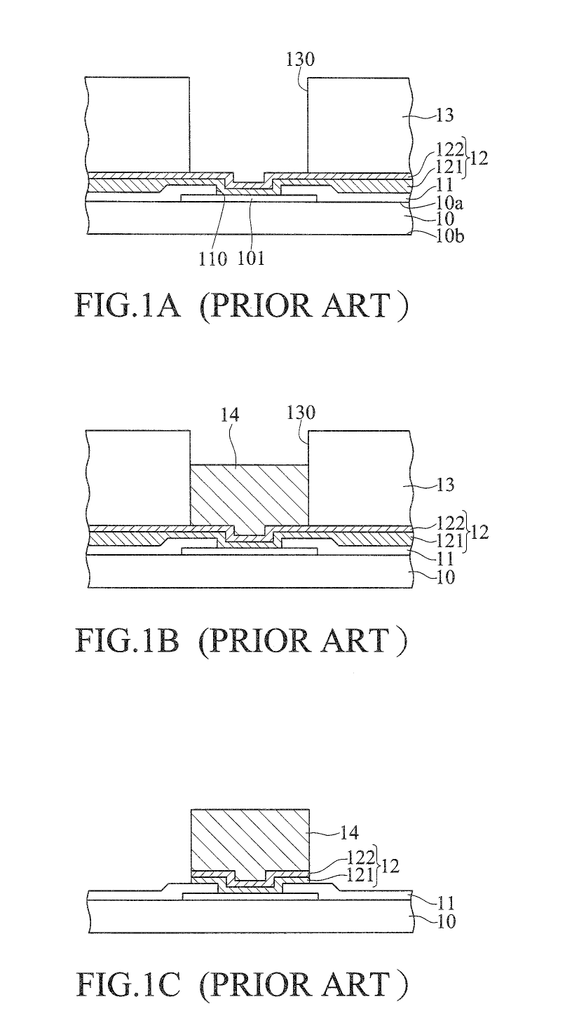

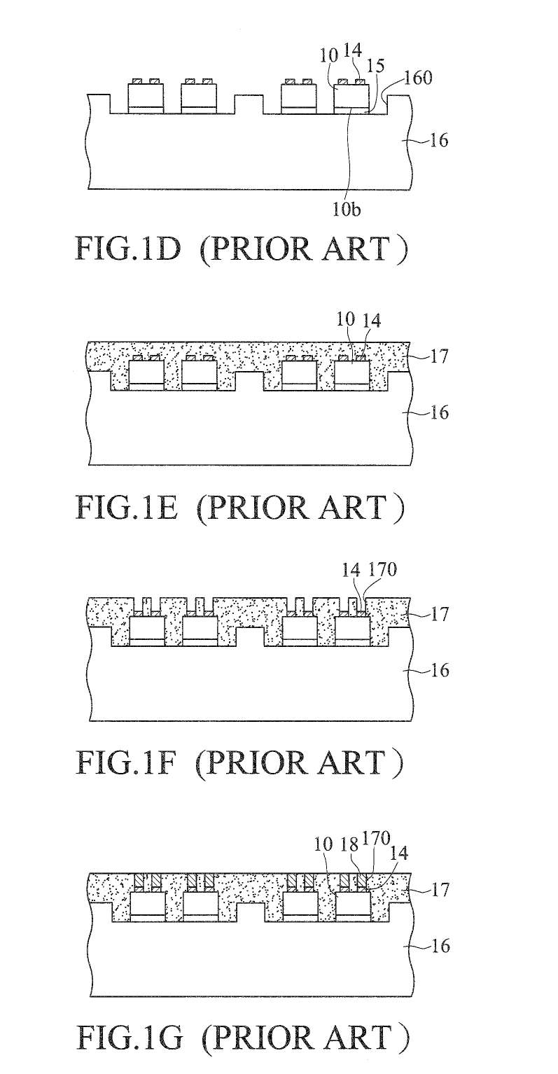

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the present invention.

It should be noted that all the drawings are not intended to limit the present invention. Various modification and variations can be made without departing from the spirit of the present invention. Further, terms used in the present invention are merely for illustrative purpose and should not be construed to limit the scope of the present invention.

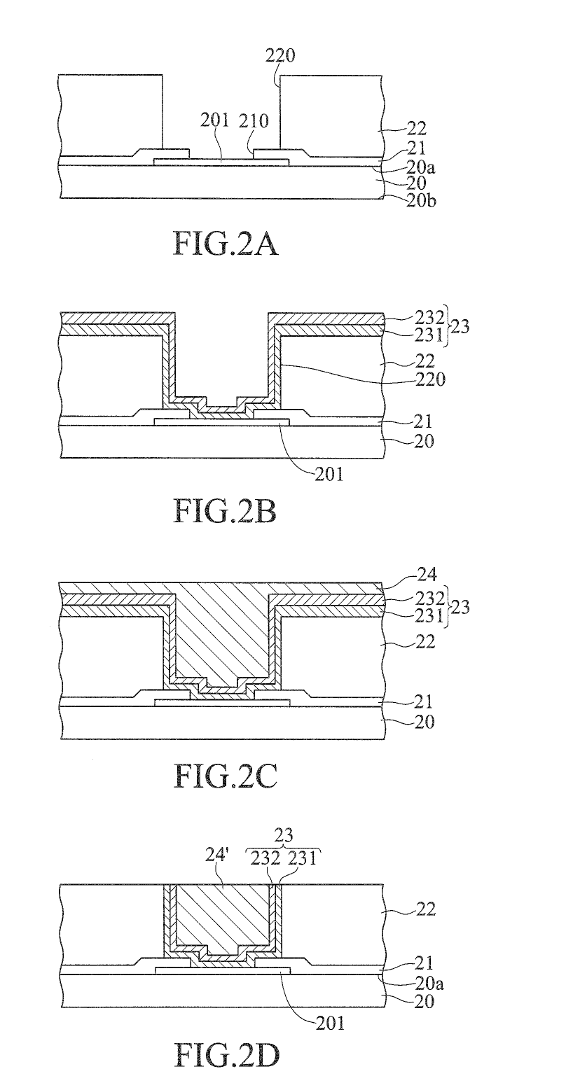

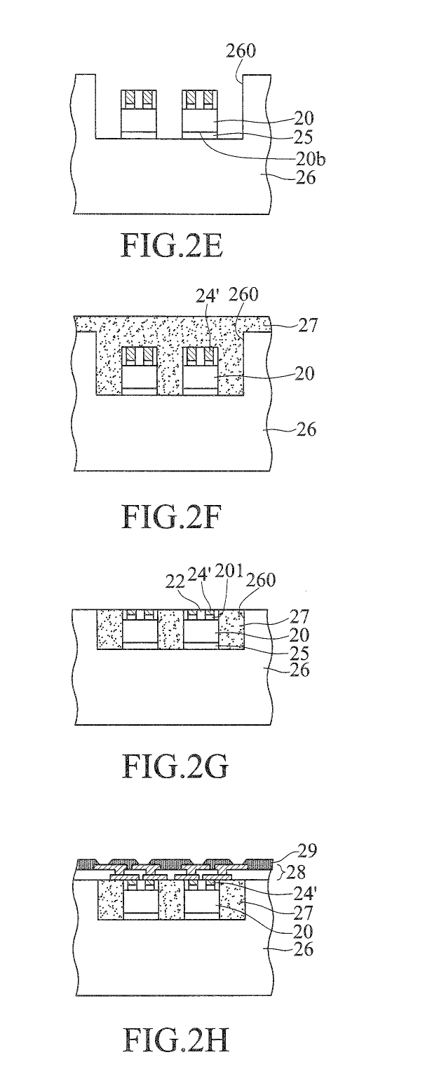

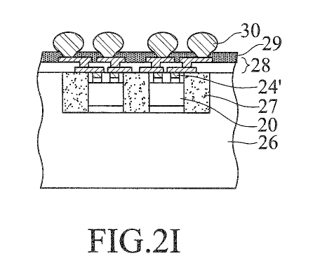

FIGS. 2A-2I are cross-sectional views illustrating a method of fabricating a semiconductor structure of a first embodiment according to the present invention.

As shown in FIG. 2A, a semiconductor chip 20 having opposing active and non-active surfaces 20a and 20b is provided. A plurality of electrode pads 201 are formed on the active surface 20a of the semiconductor chip 20. A passivation layer 21 having a plurality of passivation layer holes 210 is formed on the electrode pads 201 and on the active surface 20a. The passivation layer holes 210 correspond in position to the exposed electrode pads 201. A dielectric layer 22 having a plurality of holes 220 is formed on the passivation layer 21, with the electrode pads 201 exposed from the corresponding holes 220. The dielectric layer 22 can be formed by a photosensitive insulating material or a resist material.

As shown in FIG. 2B, a titanium sub-layer 231 and a copper sub-layer 232 that serve as a under bump metallogy layer 23 are sequentially formed on the dielectric layer 22, the walls of the holes 220, and the electrode pads 201 exposed from the holes 220.

As shown in FIG. 2C, a metal layer 24 is formed on the copper layer 232. In an embodiment, the metal layer 24 is made of copper.

As shown in FIG. 2D, a portion of the metal layer 24 that is higher than the dielectric layer 22 and the under bump metallogy layer 23 is grinded and removed, while the metallic pillars 24′ on the electrode pads 201 are retained. A under bump metallogy layer 23 is formed between the metallic pillars 24′ and the active surface 20a and on the side surfaces of the metallic pillars 24′. The dielectric layer 22 encapsulates the metallic pillars 24′ and the under bump metallogy layer 23, and is flush with the end surfaces of the metallic pillars 24′. The dielectric layer 22 can be removed according to practical needs (not shown). As shown in FIG. 2E, an adhesive layer 25 is used to adhere the semiconductor chip 20 to the bottom surface of the groove 260 of the carrier 26 via the non-active surface 20b of the semiconductor chip 20. In an embodiment, the carrier 26 does not have the groove 260. The carrier 26 can be a wafer, a glass board or a metal board.

In an embodiment, a wafer having a plurality of semiconductor chips is provided. The wafer is singulated by a singulation process after the fabrication processes described in 2A-2D, to form a plurality of semiconductor chips 20, as shown in FIG. 2E. The semiconductor chips 20 are attached to the carrier 26, for the subsequent processes to be performed.

As shown in FIG. 2F, an encapsulant 27 is formed on the carrier 26 and encapsulates the semiconductor chip 20 and the metallic pillars 24′. In an embodiment, the encapsulant 27 is further formed in the groove 260.

As shown in FIG. 2G, a grinding process is performed to remove a portion of the thickness of the encapsulant 27 and the metallic pillars 24′, as well as a portion of the thickness of the carrier 26 and the dielectric layer 22 according to practical needs, allowing the surface of the encapsulant 27 to be flush with the end surfaces of the metallic pillars 24′.

As shown in FIG. 2H, a redistribution layer 28 is formed on the encapsulant 27 and the metallic pillars 24′ and electrically connected with the semiconductor chip 20. An insulative protecting layer 29 is formed on the redistribution layer 28, and a portion of the redistribution layer 28 is exposed from the insulative protecting layer 29.

As shown in FIG. 2I, a plurality of solder balls 30 are formed on the redistribution layer 28.

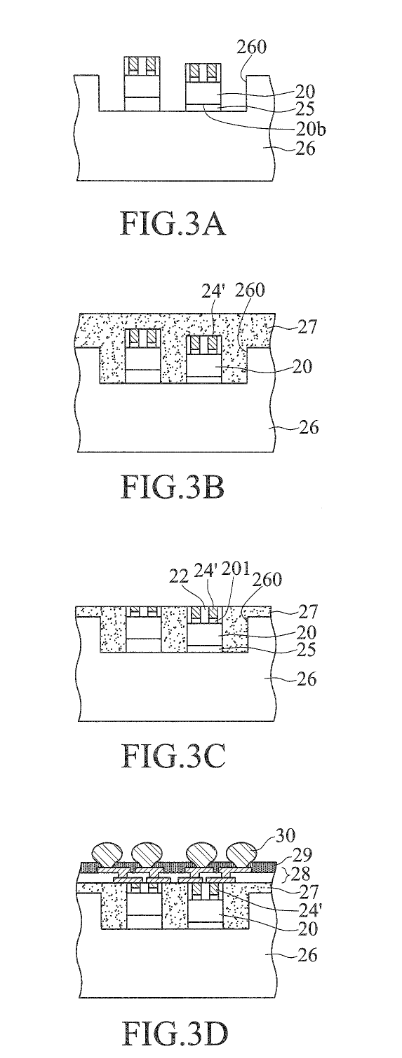

FIGS. 3A-3D are cross-sectional views illustrating a method of fabricating a semiconductor structure of a second embodiment according to the present invention. The second embodiment differs from the first embodiment in that in the second embodiment the thickness of the semiconductor chips 20 or the thickness of the adhesive layer 25 on the non-active surface 20b are different from those in the first embodiment. In the second embodiment, the semiconductor chip 20 and the metallic pillars 24′ are positioned at different heights. However, the implementation is not influenced by this difference.

The present invention provides a semiconductor structure comprising a carrier 26, a semiconductor chip 20, and an encapsulant 27. The semiconductor chip 20 is formed on the carrier 26, and has a non-active surface 20b coupled with the carrier 26 and an active surface 20a opposing the non-active surface 20b. A plurality of metallic pillars 24′ are formed on the active surface 20a. An under bump metallogy layer 23 is formed between the metallic pillars 24′ and the active surface 20a and on the side surfaces of the metallic pillars 24′. The encapsulant 27 is formed on the carrier 26 and encapsulates the semiconductor chip 20. The surface of the encapsulant 27 is flush with the end surfaces of the metallic pillars 24′.

In an embodiment, a dielectric layer 22 is formed on the active surface 20a of the semiconductor chip 20, encapsulates the metallic pillars 24′ and the under bump metallogy layer 23, and is flush with the end surfaces of the metallic pillars 24′. The dielectric layer 22 is made of a photosensitive insulating material or a resist material.

In an embodiment, the carrier 26 further comprises a groove 260, the semiconductor chip 20 is mounted on the bottom surface of the groove 260 and received in the groove 260, and the encapsulant 27 is formed in the grooves 260.

In an embodiment, the under bump metallogy layer 23 comprises a titanium sub-layer 231 and a copper sub-layer 232 formed between the metallic pillars 24′ and the titanium sub-layer 231. The packaging structure further comprises a redistribution layer 28 formed on the encapsulant 27 and the metallic pillars 24′ and electrically connected with the semiconductor chip 20.

Compared to the prior art, the present invention is characterized by forming a dielectric layer exposing the electrode pads, forming an under bump metallogy layer and a metal layer, and removing a portion of the under bump metallogy layer and the metal layer, so as to solve the unevenness of conventional metallic pillars. Moreover, an encapsulant is formed to encapsulate the semiconductor chip and the metallic pillars after the semiconductor chip is coupled to the carrier, and the encapsulant and the metallic pillars are subsequently grinded to expose the metallic pillars. As a result, the conventional method of forming encapsulant holes are not required, thereby solving the conventional problems in the prior art such as alignment deviation, and uneven thickness of the semiconductor chip and the adhesive layer.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor structure, comprising:
a semiconductor chip having a non-active surface and an active surface opposing the non-active surface;
a plurality of metallic pillars formed on the active surface; and
an under bump metallogy layer formed between the metallic pillars and the active surface and on side surfaces of the metallic pillars.

2. The semiconductor structure of claim 1, further comprising a dielectric layer formed on the active surface of the semiconductor chip, encapsulating the metallic pillars and the under bump metallogy layer, and being flush with end surfaces of the metallic pillars.

3. The semiconductor structure of claim 2, wherein the dielectric layer is formed by a photosensitive insulating material or a resist material.

4. The semiconductor structure of claim 1, wherein the under bump metallogy layer comprises a titanium sub-layer and a copper sub-layer formed between the titanium sub-layer and the metallic pillars.

5. The semiconductor structure of claim 1, further comprising:
a carrier coupled to the non-active surface of the semiconductor chip; and
an encapsulant formed on the carrier, encapsulating the semiconductor chip, and having a surface flush with end surfaces of the metallic pillars.

6. The semiconductor structure of claim 5, wherein the carrier comprises a groove, the semiconductor chip is mounted on a bottom surface of the groove, and the encapsulant is formed in the groove.

7. The semiconductor structure of claim 5, further comprising a redistribution layer formed on the encapsulant and the metallic pillars and electrically connected with the semiconductor chip.

8. A method of fabricating a semiconductor structure, comprising:
disposing on a carrier a semiconductor chip having opposing active and non-active surfaces, with the non-active surface being coupled to the carrier, wherein a plurality of metallic pillars are formed on the active surface, and an under bump metallogy layer is formed between the metallic pillars and the active surface and on side surfaces of the metallic pillars; and
forming on the carrier an encapsulant that encapsulates the semiconductor chip and has a surface flush with end surfaces of the metallic pillars.

9. The method of claim 8, further comprising grinding the encapsulant in order to remove a portion of the encapsulant and a portion of each of the metallic pillars, such that an overall thickness of the semiconductor structure is reduced to a desired extent.

10. The method of claim 8, wherein the carrier comprises a groove, the semiconductor chip is received on a bottom surface of the groove, and the encapsulant is formed in the groove.

11. The method of claim 8, further comprising forming on the active surface of the semiconductor chip a dielectric layer that encapsulates the metallic pillars and the under bump metallogy layer and has a surface flush with the end surfaces of the metallic pillars.

12. The method of claim 11 wherein the dielectric layer is formed by a photosensitive insulating material or a resist material.

13. The method of claim 8, wherein the under bump metallogy layer comprises a titanium sub-layer and a copper sub-layer formed between the metallic pillars and the titanium sub-layer.

14. The method of claim 8, further comprising forming on the encapsulant and the metallic pillars a redistribution layer that is electrically connected with the semiconductor chip.

15. A method of fabricating a semiconductor structure, comprising:
forming a dielectric layer having a plurality of holes on an active surface of a semiconductor chip, with a portion of the active surface exposed from the holes;
forming an under bump metallogy layer on the dielectric layer, walls of the holes, and the portion of the active surface exposed from the holes;
forming a metal layer on the under bump metallogy layer; and
removing a portion of the metal layer and the under bump metallogy layer that is higher than the dielectric layer, and forming a plurality of metallic pillars on the portion of the active surface exposed from the holes.

16. The method of claim 15, wherein the under bump metallogy layer comprises a titanium sub-layer and a copper sub-layer formed between the metallic pillars and the titanium sub-layer.

17. The method of claim 15, wherein the portion of the metal layer and the under bump metallogy layer is removed by a grinding process.

18. The method of claim 15, further comprising, after the portion of the metal layer and the under bump metallogy layer that is higher than the dielectric layer is removed, removing the dielectric layer.
